(19) United States
(12) Patent Application Publication
(10) Pub. No.: US 2003/0214015 A1
(43) Pub. Date: Nov. 20, 2003

(54) Semiconductor device

(75) Inventor: Naoto Akiyama, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/425,616

(22) Filed: Apr. 30, 2003

(30) Foreign Application Priority Data
May 17, 2002 (JP) 2002-143895

(51) Int. Cl. H01L 29/00

(52) U.S. Cl. 257/531

(57) ABSTRACT

The semiconductor device according to the present invention having an LSI circuit and an inductor element formed on the same substrate has an interlayer insulating film formed on the substrate, a first laminated wiring layer formed on the interlayer insulating film and serves as an internal wiring of the LSI circuit, and a second laminated wiring layer formed on the interlayer insulating film and constitutes the inductor element, wherein the first and second laminated wiring layers are mutually different, and no Ti layer which makes contact with an Al alloy layer exists on the second laminated wiring layer.

### BACKGROUND OF THE INVENTION

1. Field of the Invention

The present invention relates to a semiconductor device, and more particularly to a semiconductor device equipped with an inductor element suitable for high frequency operation.

2. Description of the Prior Art

The reduction of the resistance has been one of the important factors for an inductor element indispensable for high frequency operation.

Normally, the wiring used inside the circuit of a large scale integrated circuit (LSI) makes use of a lower wiring layer while the wiring for the power supply makes use of a wiring layer which is the uppermost wiring layer or one in its vicinity, of the wiring layers of a multilayer wiring structure. In the multilayer wiring structure, the uppermost wiring layer or one in its vicinity has a thickness larger than that of the lower wiring layers. For this reason, in order to reduce the resistance of the inductor element, a method has normally been employed in which the uppermost wiring layer or one in its vicinity for the power supply wiring that has a larger thickness than the wiring layer for the LSI circuit is used for the formation of the inductor element.

FIG. 9 is a sectional view showing an example of the conventional wiring structure for the semiconductor device. It has a Ti layer 401, a TiN layer 402, an AlCu layer 403, a Ti layer 404 and a TiN layer 405 formed on an interlayer insulating film 100. The wiring layer having the lamination structure of TiN/Ti/AlCu/TiN/Ti (representing the constituent metal species of each layer enumerated sequentially from the top layer, and the same manner of representation will be adopted hereinafter) is the one normally used for the LSI wiring. However, the wiring layer having the lamination structure of TiN/Ti/AlCu/TiN/Ti or the like normally used as the LSI wiring may form a high resistance TiAl alloy 406 between the AlCu layer 403 and the TiN layer 405 in the manufacturing process of the LSI, as shown in FIG. 9. Because of this, even if an inductor element is formed using the uppermost wiring layer or one in its vicinity, the resistance of the inductor element is increased when the high resistance TiAl alloy 406 is formed, defeating the purpose of reducing the resistance of the inductor element. In other words, the mere adoption of the method of formation of an inductor element by the use of the uppermost wiring layer or a wiring layer in its vicinity is difficult to realize an inductor element that is attaining a low resistance.

Under these circumstances, as to the wiring layer that forms the inductor element, use of a wiring layer with the TiN/AlCu/TiN/Ti structure of a Ti layer 401, a TiN layer 402, an AlCu layer 403 and a TiN layer 405 formed on an interlayer insulating film 100 as shown in FIG. 10 is sometimes adopted. Alternatively, a wiring layer with the AlCu/TiN/Ti structure of a Ti layer 401, a TiN layer 402 and an AlCu layer 403 formed on an interlayer insulating film 100 as shown in FIG. 11 may be used. These are lamination structures for the wiring devised so as not to form the TiAl alloy 406

When the thickness of the TiN layer, the Ti layer, the AlCu layer, the TiN layer, and the Ti layer if the wiring layer with the TiN/Ti/AlCu/TiN/Ti structure shown in FIG. 9 are, for example, 500, 250, 8000, 500 and 250 Å, respectively, its wiring layer resistance is about 43 mΩ/mm². In contrast, when the film thickness of the TiN layer, the AlCu layer, the TiN layer and the Ti layer of the wiring layer with the TiN/AlCu/TiN/Ti structure shown in FIG. 10 are 500, 8000, 500, and 250 Å, respectively, its wiring layer resistance is reduced to about 37 mΩ/mm².

Since this technology is aimed at preventing the formation of the TiAl alloy 406 in the LSI wiring, it is achieving an acceptable effect to the extent that an inductor element of a low resistance is realized without an increase in the wiring resistance.

However, there exists the following problem in the conventional technology described in the above. Namely, when a laminated wiring structure, such as the AlCu/TiN/Ti structure (FIG. 11) or the TiN/AlCu/TiN/Ti structure (FIG. 10) in which no TiAl alloy 406 is formed, is adopted, there is introduced a problem that wiring reliability such as the resistance to electromigration is deteriorated. In other words, one needs to recognize the fact that the formation of the TiAl alloy 406 is playing the role of contributing to the resistance to electromigration of the wiring, although it has a high resistance. Therefore, without the formation of the TiAl alloy 406, the resistance to electromigration of the wiring is deteriorated. As a result, another problem of deterioration in the reliability of the LSI as a whole is generated. For example, when the resistance to electromigration of the TiN/Ti/AlCu/TiN/Ti (with the corresponding thicknesses of 500/250/8000/500/250 Å) wiring structure shown in FIG. 9 is taken 1, it is considered that the resistance to electromigration of the TiN/AlCu/TiN/Ti (with the corresponding thicknesses of 500/8000/500/250 Å) wiring structure shown in FIG. 10 deteriorates to about 0.7, and the resistance to electromigration of the AlCu/TiN/Ti (with the corresponding thicknesses of 8000/500/250 Å) wiring structure shown in FIG. 11 deteriorates to about 0.4.

Now, it is possible to avoid the deterioration in the resistance to electromigration through increase in the wiring width for the purpose of relaxing the current density, but it causes a problem of lowering the degree of integration. Since the degree of integration is often mild in the formation region of the inductor element, there are cases in which an increase in the wiring width is relatively tolerable, but in the formation region of the LSI internal circuit, an increase in the wiring width is intolerable from the design viewpoint.

Moreover, as shown in FIG. 12, there is a case in which, for a first wiring 400 with a structure of AlCu layer 403/TiN layer 402/Ti layer 401, a second interlayer insulating film 110 is formed newly on top of it, a connection hole 120 is provided in the interlayer insulating film 110, and a second wiring 700 with a wiring structure of TiN layer 705/Ti layer 704/AlCu layer 703/TiN layer 702/Ti layer 701 to be connected to the first wiring 400, is formed. Then, a contact hole connecting the first wiring 400 and the second wiring 700 is formed by depositing a TiN layer 121 on the bottom face and the side face of the connection hole 120, and embedding a W region 122 inside the space surrounded by the layer 121.

In this case, an aluminum nitride alloy 130, which is a high resistance material, is also formed in the interface between the TiN layer 121 of the connection hole 120 and the AlCu layer 403 in the lower layer, during the process of manufacture. When the high resistance aluminum nitride alloy 130 is generated in this way on the bottom face of the connection hole 120, there may arise a situation in which the electrical connection between the first wiring 400 and the second wiring 700 is insufficient.

Moreover, as shown in FIG. 13, even when the first wiring 400 has a structure of TiN layer 405/AlCu layer 403/TiN layer 402/Ti layer 401, an aluminum nitride alloy 131 already exists in the interface of the TiN layer 405 and the AlCu layer 403, so that there is a case in which the electrical connection between the first wiring 400 and the second wiring 700 is difficult These facts may lead to the obstruction of applicability of the macro function which is one of the important design techniques of the system LSIs.

In this way, the method of forming an LSI internal wiring and an inductor element by the use of wiring structures having the same lamination structure, as in the conventional method, may be said to have a limitation in regard to the point of meeting the requirements for the performance and the quality at the same time.

### BRIEF SUMMARY OF THE INVENTION

### SUMMARY OF THE INVENTION

The semiconductor device according to the present invention in which an LSI circuit and an inductor element are formed on the same substrate, has an interlayer insulating film formed on the substrate, a first laminated wiring layer formed on the interlayer insulating film and serves as an internal wiring of the LSI circuit, and a second laminated wiring layer formed on the interlayer insulating film and constitutes an inductor element, wherein the first and second laminated wiring layers are mutually different, and no Ti layer which makes contact with an Al alloy layer exists on the second laminated wiring layer.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a sectional view of a step of the manufacturing method according to a first embodiment of this invention;

FIG. 2 is a sectional view showing the step next to that in FIG. 1, which is a sectional view obtained along line A-A in FIG. 3;

FIG. 3 is a plan view showing the step next to that in FIG. 1;

FIG. 4 is a sectional view showing the step next to that shown in FIG. 2 and FIG. 3, which is a sectional view obtained along line B-B in FIG. 5;

FIG. 5 is a plan view of the step next to that shown in FIG. 2 and FIG. 3;

FIG. 6 is a sectional view showing a second embodiment of the invention;

FIG. 7 is a sectional view showing a third embodiment of the invention;

FIG. 8 is a sectional view showing a fourth embodiment of the invention;

FIG. 9 is a sectional view showing a conventional manufacturing method of the semiconductor device;

FIG. 10 is a sectional view showing a conventional manufacturing method of the semiconductor device;

FIG. 11 is a sectional view showing a conventional manufacturing method of the semiconductor device;

FIG. 12 is a sectional view showing a problem in the conventional technology; and

FIG. 13 is a sectional view showing a problem in the conventional technology.

### DETAILED DESCRIPTION OF THE INVENTION

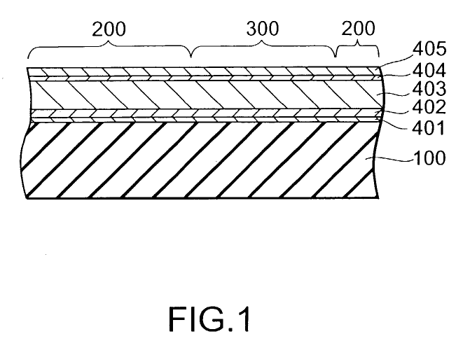

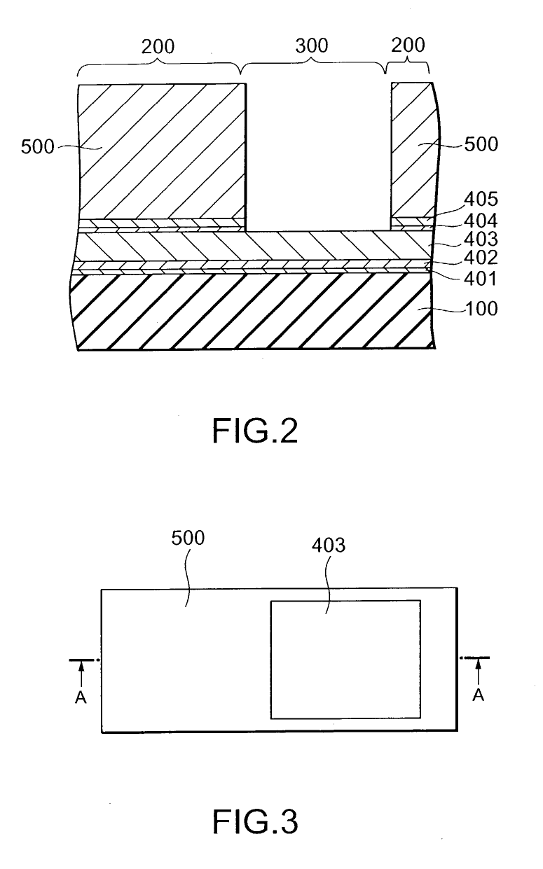

Referring to the accompanying drawings, the embodiments of the present invention will be described in detail next. FIG. 1 to FIG. 5 are drawings, given in the order of the steps, showing the manufacturing method of the semiconductor device according to a first embodiment of the invention (FIGS. 1, 2 and 4 are sectional views, and FIGS. 2 and 5 are plan views). First, as shown in FIG. 1, a wiring metal film of laminated structure consisting of, for example, a Ti layer 401 with thickness of 250 Å, a TiN layer 402 with thickness of 500 Å, an AlCu layer 403 with thickness of 8000 Å, a Ti layer 404 with thickness of 250 Å and a TiN layer with thickness of 500 Å is formed starting from the bottom, with respect to a first interlayer insulating film 100 on which an inductor element is to be formed. In FIG. 1, a normal LSI internal circuit region 200 and an inductor element region 300 are assigned adjacent with each other.

Next, as shown in FIG. 2 and FIG. 3, a photoresist 500 is formed selectively on the LSI internal circuit region 200 in a manner similar to a normal wiring process, and the TiN layer 405 and the Ti layer 404 on the AlCu layer 403 in the inductor element region 300 are removed by photolithography using the photoresist 500 and wiring working technology. As a result, the AlCu layer 403 is exposed to the inductor element region 300. After that, the photoresist 500 is removed.

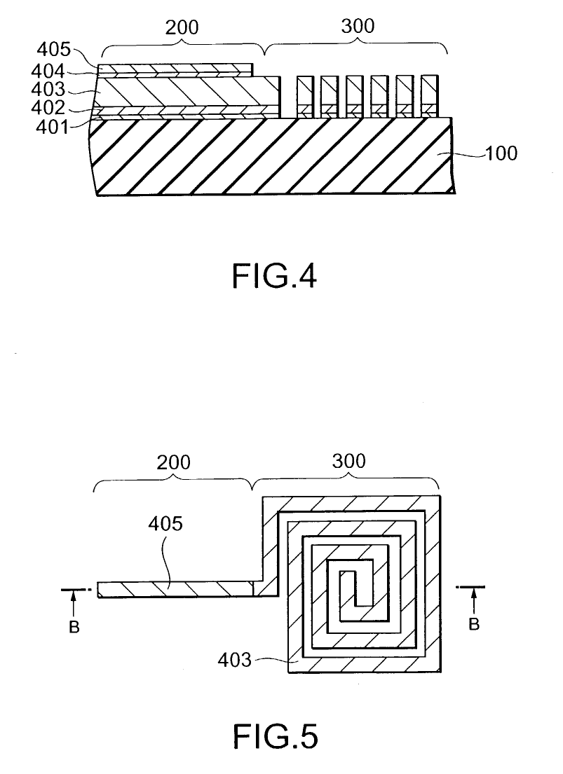

Finally, as shown in FIG. 4 and FIG. 5, a wiring pattern used in the normal LSI circuit and an inductor element pattern are formed simultaneously by using normal wiring formation processes such as photolithography and etching. In this case, since the TiN layer 405 and the Ti layer 404 are removed from the wiring layer constituting the inductor element in the process shown in FIG. 2, high resistance TiAl alloy 406 will not be formed, making it possible to form an inductor element with low resistance wirings.

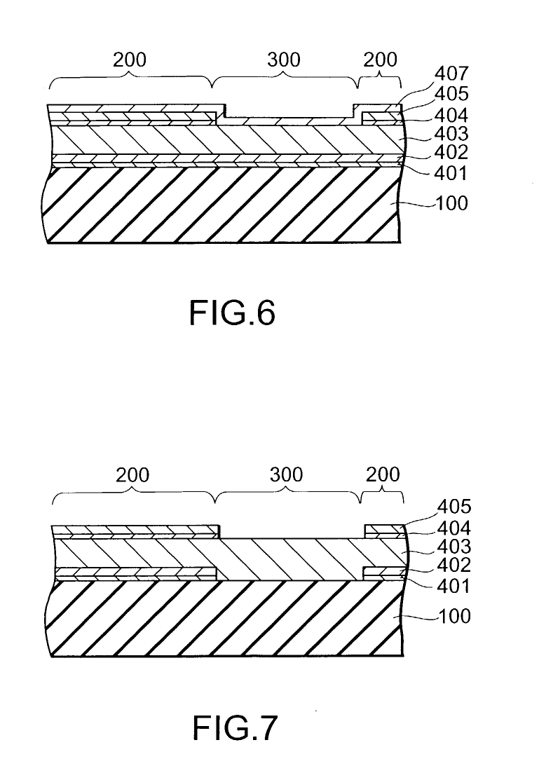

Next, referring to FIG. 6, a second embodiment of the invention will be described. In this embodiment, after removal of the TiN layer 405 and the Ti layer 404 from the inductor element region 300 as shown in FIG. 2, a TiN film 407 with thickness of 500 Å, for example, is formed on the entire surface as shown in FIG. 6. After that, by the processes similar to those shown in FIG. 3 and FIG. 5, a wiring pattern used in the normal LSI circuit and an inductor element pattern are formed simultaneously in the LSI internal circuit region 200 and in the inductor element region 300 by using the normal wiring formation processes such as photolithography and etching.

In this embodiment configured as in the above, since inductor element region 300 is given the wiring structure TiN/AlCu/TiN/Ti, it is possible to prevent the formation of the high resistance TiAl alloy similar to the first embodiment, and moreover, it is possible to prevent the deterioration in the resistance to electromigration of the inductor element by the presence of the TiN film 407. Accordingly, the wiring width of the inductor element can be reduced, and an inductor element with low resistance having a high resistance to electromigration can be formed.

FIG. 7 is a sectional view showing the manufacturing method of the semiconductor device according to a third embodiment of the invention. As shown in FIG. 7, a five-layer laminated wiring structure of a Ti layer 401, a TiN layer 402, an AlCu layer 403, a Ti layer 404 and a TiN layer 405 is formed in the LSI internal circuit region 200. However, in the inductor element region 300, the Ti layer 404 and the TiN layer 405 below the AlCu layer 403 may be omitted, and the inductor element in the inductor element region 300 may be formed exclusively of the AlCu layer 403.

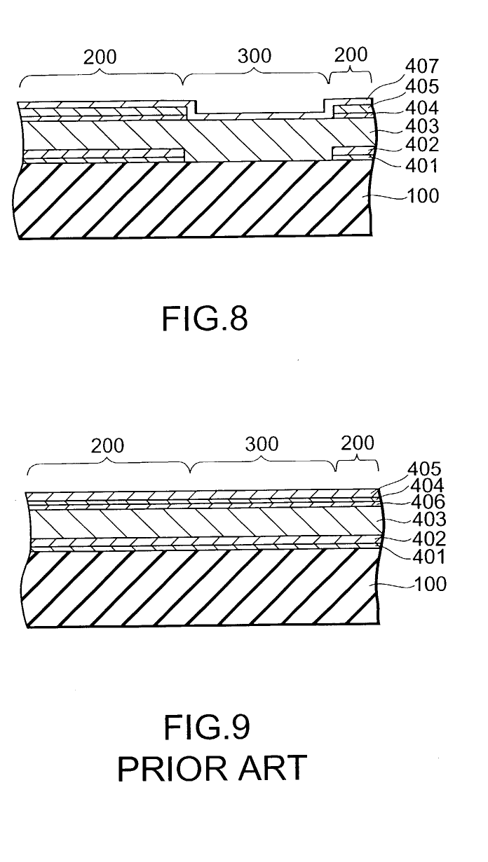

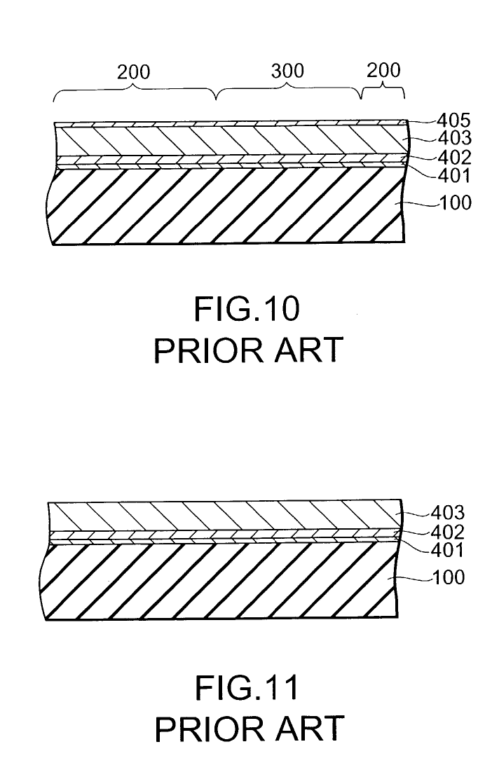

FIG. 8 is a sectional view showing the manufacturing method of the semiconductor device according to a fourth embodiment of the invention. As shown in FIG. 8, in this embodiment, a TiN layer 407 is formed on the entire surface as in the third embodiment in FIG. 7, and the inductor element region 300 is composed of the AlCu layer 403 and its upper layer, TiN film 407.

In the embodiments shown in FIG. 7 and FIG. 8, patterning in the form of the LSI internal circuit and the inductor element is performed in the following stages similar to FIG. 4 and FIG. 5.

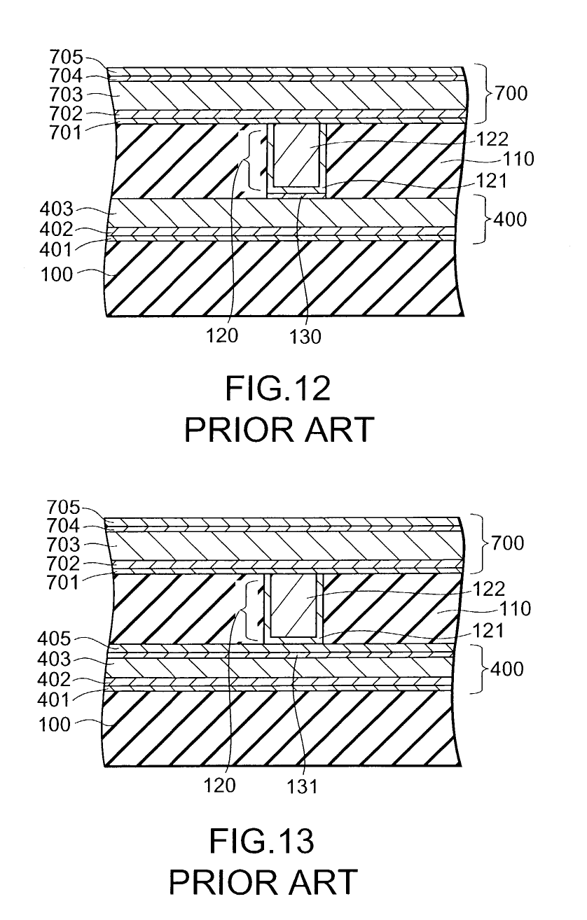

Moreover, in this invention, it may be arranged to form a second (another) interlayer insulating film, on the laminated wiring layer (first laminated wiring layer) for the LSI internal circuit region 200 and the laminated wiring layer (second laminated wiring layer) for the inductor element region 300, as in FIG. 12 and FIG. 13, form another wiring layer (second wiring 700; see FIG. 12 and FIG. 13) on top of it, and form a multilayer wiring structure by connecting the first laminated wiring layer and the second laminated wiring layer by a contact hole (connection hole 120). In this case, since the TiN layer 405 is formed as the topmost layer of the first laminated wiring layer according to the present embodiment, aluminum nitride alloy 130 will not be formed between the TiN layer 121 on the bottom face of the contact hole as shown in FIG. 12. Moreover, since the first laminated wiring layer has the Ti layer 404 formed between the topmost TiN layer 405 and the AlCu layer 403 in this embodiment, the aluminum nitride film 131 will not be formed as indicated in FIG. 13. Here, another wiring layer mentioned above maybe made as a single wiring layer rather than a laminated wiring layer, as is the case, in the second wiring 700 (see FIGS. 12 and 13).

Furthermore, in the above embodiments, the first laminated wiring layer and the second laminated wiring layer of the invention are formed on the interlayer insulating film 100 on the substrate. However, the first and second laminated wiring layers may be formed as wiring layers in upper layers in a multilayer wiring structure.

As described in detail in the above, according to the present invention, in a semiconductor device having a normal LSI circuit and an inductor element indispensable for a high frequency device are formed on the same substrate, a second laminated wiring layer to be used for the inductor element is given a different configuration from a first laminated wiring structure to be used for the LSI internal circuit so as not to form TiAl alloy in the second laminated wiring layer. Accordingly, the resistance of the inductor element can be reduced, and at the same time its resistance to electromigration can be made sufficiently high. As a result, a semiconductor device that is capable of coping with high frequency operation and is suitable for a system LSI can be obtained.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A semiconductor device having an LSI circuit and an inductor element formed on the same substrate comprising, an interlayer insulating film formed on said substrate, a first laminated wiring layer formed on said interlayer insulating film and serves as an internal wiring of said LSI circuit, and a second laminated wiring layer formed on said interlayer insulating film and constitutes said inductor element, wherein said first and second laminated wiring layers are mutually different and no Ti layer which makes contact with an Al alloy layer exists on said second laminated wiring layer.

2. The semiconductor device as claimed in claim 1, wherein said first laminated wiring layer has an AlCu layer, a Ti layer on top of it and a TiN layer further on top of it, and said second laminated wiring layer has an AlCu layer as said Al alloy layer.

3. The semiconductor device as claimed in claim 2, wherein a TiN layer is formed on top of said AlCu layer of said second laminated wiring layer.

4. The semiconductor device as claimed in claim 2, wherein a TiN layer is formed below said AlCu layer of said first laminated wiring layer and a Ti layer is formed further below it.

5. The semiconductor device as claimed in claim 2, further comprising another interlayer insulating film formed on said first laminated wiring layer, another wiring layer formed on said another interlayer insulating layer, and a contact hole formed in said another interlayer insulating film for connecting said first laminated wiring layer and said another wiring layer, wherein said contact hole has a connection hole formed selectively in said another interlayer insulating film, a TiN layer formed on the bottom face and the side face of said connection hole, and an embedded metal region embedded in said connection hole.
